(19) United States
(12) Patent Application Publication
(10) Pub. No.: US 2023/0411152 A1
(43) Pub. Date: Dec. 21, 2023

(54) Substrate For Epitaxial Growth, Manufacturing Method of the Same, Semiconductor Device Including the Same and Manufacturing Method Using the Same

(71) Applicant: FUJIAN JING' AN OPTOELECTRONICS CO., LTD., Quanzhou City (CN)

(72) Inventors: Bohsiang TSENG, Quanzhou City (CN); Jiahao ZHANG, Quanzhou City (CN); Jiayue HONG, Quanzhou City (CN); Liang YANG, Quanzhou City (CN); Juiping LI, Quanzhou City (CN); Mingxin CHEN, Quanzhou City (CN)

(21) Appl. No.: 18/451,511

(22) Filed: Aug. 17, 2023

Related U.S. Application Data
(63) Continuation-in-part of application No. 17/359,759, filed on Jun. 28, 2021.

(30) Foreign Application Priority Data
Jun. 29, 2020 (CN) 202010601306.8
Dec. 30, 2022 (CN) 202211723194.9

(51) Int. Cl. H01L 21/02; H01L 33/00

(52) U.S. Cl. CPC H01L 21/0243; H01L 21/0203; H01L 21/0254; H01L 33/007

(57) ABSTRACT

A substrate for epitaxial growth includes a first surface to be processed, and a second surface opposite to the first surface. When being viewed from above the first surface, the substrate is divided into a modified region and a non-modified region. The modified region is partitioned from the non-modified region by a border which is located at a predetermined position in the substrate, and has a plurality of modified points.

### CROSS-REFERENCE TO RELATED APPLICATION

This application claims priority of Chinese Invention Patent Application No. 202211723194.9, filed on Dec. 30, 2022. This application is also a continuation-in-part application of U.S. patent application Ser. No. 17/359,759, filed on Jun. 28, 2021, which claims priority to Chinese Invention Patent Application No. 202010601306.8, filed on Jun. 29, 2020. Each of the U.S. patent application and the Chinese invention patent applications is incorporated by reference herein in its entirety.

### FIELD

The disclosure relates to semiconductors, and more particularly to a substrate for epitaxial growth, a manufacturing method for manufacturing the substrate, a semiconductor device including the substrate, and a manufacturing method using the substrate.

### BACKGROUND

Generally, methods for processing substrates include an epitaxial growth process, cutting, grinding, annealing, copper grinding, polishing, etc. However, these methods are unable to control the shape and amount of warpage of substrates.

### SUMMARY

Therefore, an object of the disclosure is to control and improve a surface profile of a substrate for epitaxial growth, which is beneficial for improving the yield of semiconductor products.

According to a first aspect of the disclosure, a substrate includes a first surface to be processed and a second surface opposite to the first surface. When being viewed from above the first surface, the substrate is divided into a modified region and a non-modified region. The modified region is partitioned from the non-modified region by a border which is located at a predetermined position in the substrate. The modified region has a plurality of modified points.

According to a second aspect of the disclosure, a substrate manufacturing method includes: providing a substrate having a first surface for epitaxial growth and a second surface opposite to the first surface; determining a location of a border to divide the substrate into a first area for forming a modified region and a second area for serving as a non-modified region; and laser scanning the first area to form a plurality of modified points in the first area of the substrate through multi-photon absorption so that the first area is formed into the modified region.

According to a third aspect of the disclosure, a method for manufacturing a semiconductor device includes: providing a substrate for epitaxial growth, the substrate having a first surface and a second surface opposite to the first surface, the substrate including a modified region and a non-modified region partitioned from the modified region by a border which is located at a predetermined position in the substrate, the modified region having a plurality of modified points distributed in the modified region when being viewed from above the first surface; and forming at least one semiconductor epitaxial layer on the first surface of the substrate.

According to a fourth aspect of the disclosure, a semiconductor device includes a substrate for epitaxial growth, and at least one semiconductor epitaxial layer disposed on the substrate for epitaxial growth. The substrate for epitaxial growth includes a first surface to be processed and a second surface opposite to the first surface. When being viewed from above the first surface, the substrate is divided into a modified region and a non-modified region. The modified region is partitioned from the non-modified region by a border which is located at a predetermined position in the substrate. The modified region has a plurality of modified points.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIGS. 1A to 1C are schematic views illustrating various curvature distributions measured by a flatness measuring instrument for sapphire substrates having different distorted surface profiles due to uneven stress distribution therein.

FIG. 1D is a schematic view illustrating a curvature distribution obtained for a substrate that has a uniform stress distribution.

FIG. 2 is a flow diagram illustrating a substrate manufacturing method in accordance with a first embodiment of the disclosure.

FIG. 3A is a schematic side view of a substrate used in the first embodiment of the disclosure.

FIG. 3B is a schematic top view that is viewed from above a first surface of the substrate of FIG. 3A.

FIGS. 4 to 7 are schematic views illustrating examples of a scan pattern in accordance with the first embodiment of the disclosure.

FIG. 8 is a view illustrating a distribution of modified points in the substrate in accordance with the first embodiment of the disclosure.

FIG. 9 is a box plot showing warpage of comparative examples that are not irradiated by a laser beam and warpage of examples that are irradiated by the laser beam.

FIG. 10 is a flow diagram illustrating a method for manufacturing a semiconductor device in accordance with a second embodiment of the disclosure.

FIG. 11 is a schematic view illustrating the semiconductor device obtained by the method of FIG. 10.

FIG. 12 is a graph showing variation of average and standard deviation of warpage during epitaxial growth of the comparative examples that are not irradiated by a laser beam and the examples that are irradiated by the laser beam in accordance with the second embodiment of the disclosure.

FIG. 13 is a diagram illustrating an emission wavelength distribution of a substrate after epitaxial growth and having an even stress distribution therein.

FIG. 14 is a flow diagram illustrating a substrate manufacturing method in accordance with a third embodiment of the disclosure.

FIG. 15 is a schematic top view illustrating a substrate divided into a first area and a second area in accordance with the third embodiment of the disclosure.

FIGS. 16 and 17 are schematic views illustrating two examples of a scan pattern at the first area in accordance with the third embodiment of the disclosure.

FIG. 18 a SEM image showing a modified region of the substrate in accordance with the third embodiment of the disclosure.

FIG. 19 is a schematic side view of the substrate in accordance with the third embodiment of the disclosure.

FIG. 20 is a diagram similar to FIG. 13, but illustrating an emission wavelength distribution of the substrate after epitaxial growth in accordance with the third embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Preparation of substrates for epitaxial growth plays an important role for manufacturing semiconductor devices. For example, sapphire substrates are often used for supporting nitride-based epitaxial structures that emit from visible light wavelengths to ultraviolet light wavelengths. Because substrates for epitaxial growth are generally thin, mechanically processing the substrates usually causes the substrates to bend, twist and/or warp due to uneven stress distributions in the substrates. This directly affects the yield of substrates and the performance of semiconductor devices.

A substrate for epitaxial growth may exhibit different kinds of surface profiles when deformation, such as distortion, bending, and/or warping, occurs due to uneven stress distribution therein. Such deformation of the substrate for epitaxial growth mainly occurs in a peripheral region of the substrate, while a central region thereof that is surrounded by the peripheral region is flat without being deformed and has a radius of no less than 10 mm.

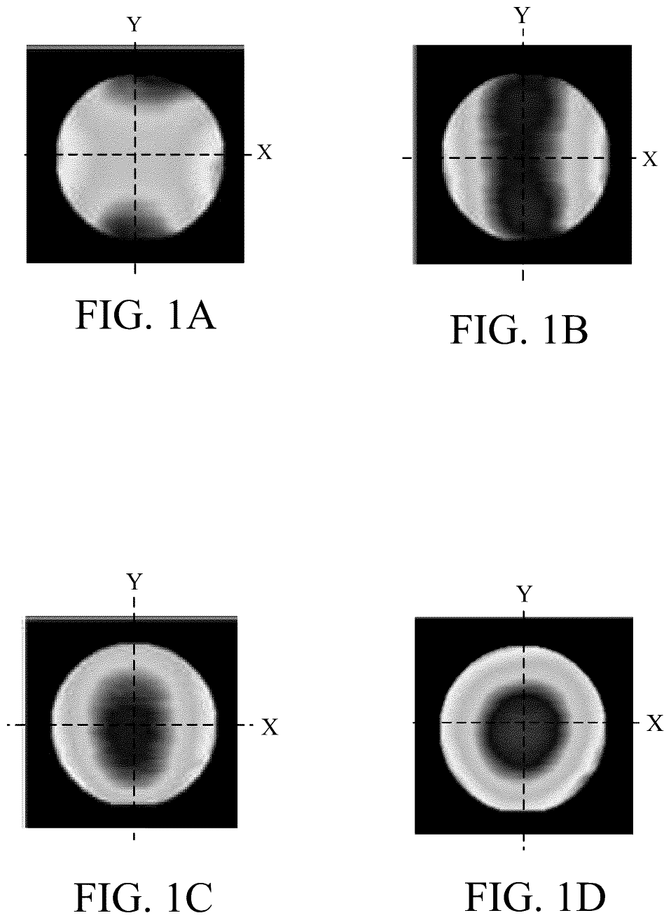

Referring to FIGS. 1A to 1D, four surface profiles of sapphire substrates are shown as examples. Each example has a first surface, a second surface opposite to the first surface. For example, the first surface may be a front facing surface of the sapphire substrate, while the second surface may be the back facing surface. Furthermore, each example has a central region, a peripheral region surrounding the central region, a horizontal axis (X), and a vertical axis (Y) which are perpendicular to each other. Curvature distributions of the examples are measured from the first surfaces thereof by a flatness measuring instrument. Generally, sapphire substrates exhibit four types of surface profiles as shown in FIGS. 1A to 1D.

In the example shown in FIG. 1A, the peripheral region along the horizontal axis (X) is bent toward the first surface and the peripheral region along the vertical axis (Y) is bent toward the second surface. Such a surface profile is often referred to as a saddle-type profile.

In the example shown in FIG. 1B, the peripheral region along the horizontal axis (X) is bent toward one of the first surface and the second surface, while the peripheral region along the vertical axis (Y) is flat with no bending. Such a surface profile is often referred to as a cylinder-type profile.

In the example shown in FIG. 10, the peripheral regions along both of the horizontal axis (X) and the vertical axis (Y) are bent toward one of the first surface and the second surface. The resulting curvatures along the horizontal axis (X) and the vertical axis (Y) are equally distant from the center of the substrate, and the degree of curvature along the horizontal axis (X) is larger than that along the vertical axis (Y). Such a surface profile is often referred to as a concentric ellipses-type profile.

In the example shown in FIG. 1D, the point of curvature of the peripheral regions are located at positions equally distant from the center in all radial directions, and are bent toward the same surface (i.e., the first surface or the second surface). The degree of curvature at the positions are almost the same. Such a surface profile is often referred to as a concentric circles-type profile. The sapphire substrate of the concentric circles-type has a relatively even stress distribution, and has a relatively uniform curvature distribution (i.e., a relatively consistent degree of curvature at the positions), which is beneficial for the consistency of the wavelength of light emitted from the substrate after epitaxial growth.

### Embodiment 1

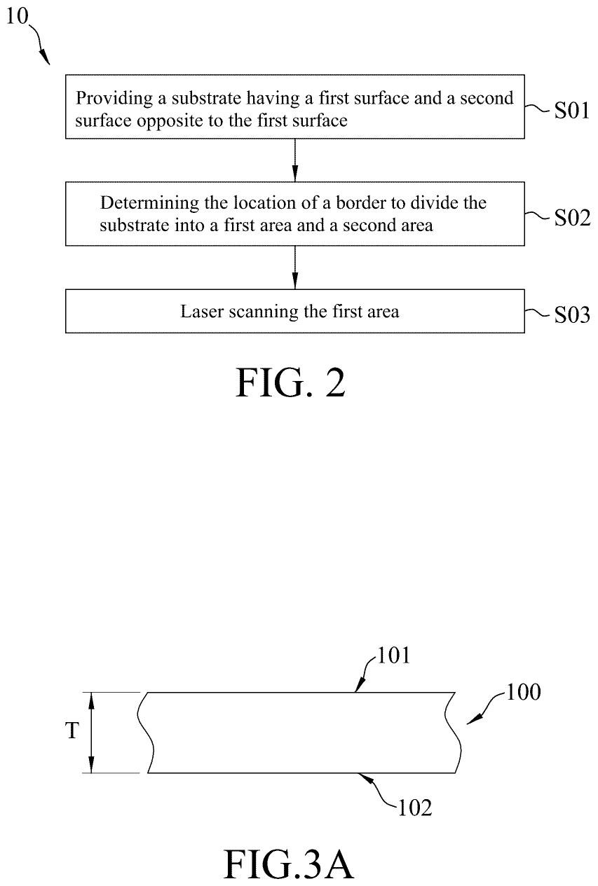

In view of the abovementioned characteristics of the surface profiles of the sapphire substrates, a substrate manufacturing method is provided to produce a substrate which is used for epitaxial growth and which has a surface profile with improved uniformity of curvature distribution. Referring to FIG. 2, a substrate manufacturing method 10 in accordance with a first embodiment of the disclosure includes steps S01, S02 and S03.

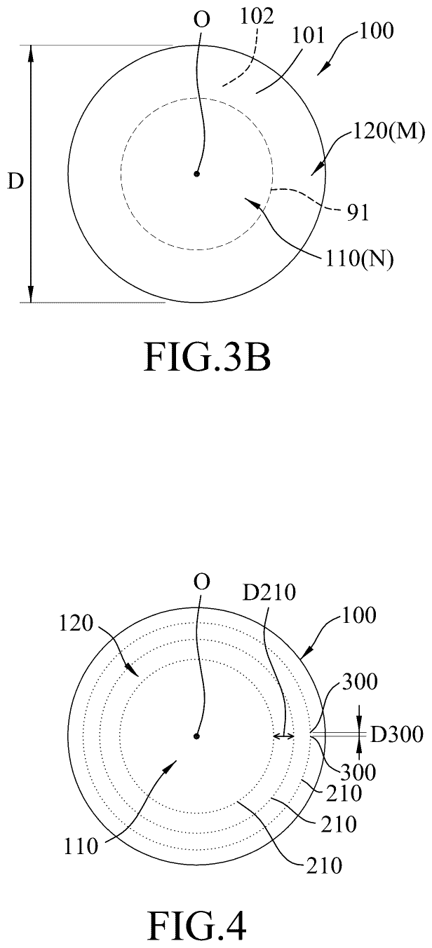

In step S01, a substrate 100 for epitaxial growth is provided. As shown in FIG. 3A, the substrate 100 has a first surface 101 for epitaxial growth and a second surface 102 opposite to the first surface 101. When the substrate is viewed from above the first surface 101, the substrate 100 has a center point (O) (see FIG. 3B).

In step S02, as shown in FIG. 3B, the location of a border 91 to divide the substrate 100 into a first area 120 and a second area 110 is determined. The first area 120 is for forming a modified region (M) of the substrate 100 and the second area 110 is for serving as a non-modified region (N) of the substrate 100. The border 91 is between the first and second areas 120, 110. In this embodiment, the first area 120 is spaced apart from the center point (O) of the substrate 100 by a distance, and surrounds the second area 110. Thus, in this embodiment, the first area 120 and the second area 110 may be also referred to as a peripheral region and a central region, respectively.

The substrate 100 can be made from any substrate material suitable for epitaxial growth. In this embodiment, the substrate 100 is made of sapphire, which is able to absorb multiple photons so as to form a plurality of modified points 300 (see FIG. 8) in an interior of the substrate, thereby improving stress distribution in the substrate 100. The substrate 100 has a thickness (T) (see FIG. 3A) ranging from about 50 μm to about 20 mm, and a diameter (D) (see FIG. 3B) ranging from about 4 inches to about 18 inches. The central region 110 may have a shape of a square, a circle, or a polygon. As shown in FIG. 3B, in some embodiments, the central region 110 is a circular region, and has a radius of at least 10 mm. Since the border 91 that divides the substrate 100 is between the central region 110 and the peripheral region 120, the location of the border 91 is determined based on the radius of the central region 110. Determination of the radius of the central region 110 will be described later in the disclosure.

In step S03, as shown in FIG. 8, the first area 120 is laser scanned to form a plurality of the modified points 300 inside a portion of the substrate 100 within the first area 120 (i.e., the peripheral region), thereby forming the modified region 120 of the substrate 100. Specifically, the modified points 300 are formed by laser scanning the first area (i.e., peripheral region) 120 in an intermittent manner along a scan pattern arranged in the peripheral region 120, wherein the modified points 300 are formed through multi-photon absorption in the interior of the portion of the substrate 100 within the peripheral region 120 in a continuous or discontinuous manner. In some embodiments, the laser beam is generated by a pulsed laser. During the laser scanning process, the laser beam moving at a predetermined rate and direction intermittently scans the first area 120 of the first surface 101 of the substrate 100. Discrete laser dots that are located at different positions form the scan pattern, and the modified points 300 are formed along the scan pattern in a continuous or discontinuous manner.

The scan pattern may include a plurality of circular lines, a plurality of linear lines, or a combination of circular lines and linear lines. In some embodiments, the circular lines may be a plurality of concentric circles that are centered at the center point (O) of the substrate 100. In some embodiments, the linear lines may be radially-extending lines, grid lines, parallel lines, or non-parallel lines.

Referring to FIG. 4, a first example of the scan pattern includes a plurality of concentric circles 210 on the peripheral region 120. The modified points 300 are distributed along the concentric circles 210 in a continuous or discontinuous manner in the interior of the substrate 100, and are formed by intermittently irradiating the peripheral region 120 with the laser beam along the concentric circles 210. The modified points 300 are thereby formed in the peripheral region 120 along the concentric circles 210 that are centered at the center point (O) of the substrate 100.

Referring back to FIGS. 1A, 1B, 1C and 1D, it is observed that for each example of the sapphire substrates, the central region that is flat and not deformed has a radius of at least 10 mm. Since the central regions shown in FIGS. 1A to 1D are flat and not deformed, the central regions need not be modified. Therefore, the radius of the central region 110 in this embodiment is determined to be at least 10 mm, and the distance of the peripheral region 120 from the center point (O) should therefore be no less than 10 mm. The location of the border 91 between the central and peripheral regions 110, 120 is determined to be at a distance of at least 10 mm from the center (O) of the substrate 100. Therefore, in this embodiment, the modified points 300 are not formed in the central region 110 of the substrate 100 to adjust stress distribution therein. Since the distance between the peripheral region 120 and the center point (O) of the substrate 100 is no less than 10 mm, a smallest one of the concentric circles 210 may have a radius which is 10 mm. That is to say, each of the modified points 300 is spaced apart from the center point (O) of the substrate 100 by a distance of no less than 10 mm. Furthermore, a spacing D300 between two adjacent ones of the modified points 300 is smaller than the minimum radius of the concentric circles 210, i.e., 10 mm. In some embodiments, the spacing D300 is not larger than 1 mm. In addition, a spacing D210 between two adjacent ones of the concentric circles 210 is smaller than the distance by which the peripheral region 120 is spaced apart from the center point (O) of the substrate 100. In some embodiments, the spacing D210 ranges from 20 μm to 10 mm.

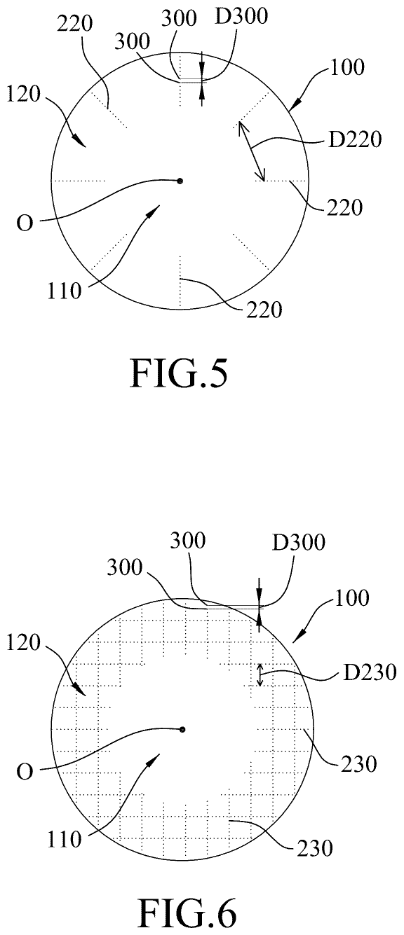

Referring to FIG. 5, a second example of the scan pattern includes a plurality of radially-extending lines 220 that are directed toward the center point (O) of the substrate 100. Each of the radially-extending lines 220 initiates from an outer boundary of the peripheral region 120 (i.e., a boundary of the substrate 100), radially extends to the center point (O) of the substrate 100, and ends at the border (not shown) between the central region 110 and the peripheral region 120. The modified points 300 are distributed along the radially-extending lines 220 in a continuous or discontinuous manner in the interior of the substrate 100, and are formed by intermittently irradiating the peripheral region 120 with the laser beam along the radially-extending lines 220. The modified points 300 are thereby formed in the peripheral region 120 along the radially-extending lines 220 that are directed toward the center point (O) of the substrate 100.

Since the distance between the peripheral region 120 and the center point (O) of the substrate 100 is no less than 10 mm, each of the radially-extending lines 220 of the pattern is spaced apart radially from the center point (O) of the substrate 100 by a distance that is larger than 10 mm. That is to say, each of the modified points 300 is spaced apart from the center point (O) of the substrate 100 by a distance that is no less than 10 mm. Furthermore, two adjacent ones of the modified points 300 have a spacing D300 therebetween. The spacings D300 may be uniform or non-uniform. The spacing D300 is smaller than a minimum distance of the modified points 300 to the center point (O) of the substrate 100, i.e., 10 mm. In some embodiments, the spacing D300 is not larger than 1 mm. In addition, two adjacent ones of the radially-extending lines 220 have a spacing D220 therebetween that is smaller than the distance by which the peripheral region 120 is spaced apart from the center point (O) of the substrate 100. In some embodiments, the spacing D220 ranges from 20 μm to 10 mm.

Referring to FIG. 6, a third example of the scan pattern includes a plurality of lines that are perpendicular to each other so as to form a plurality of grid lines 230. The modified points 300 are distributed along the grid lines 230 in a continuous or discontinuous manner in the interior of the substrate 100, and are formed by intermittently irradiating the peripheral region 120 with the laser beam along the grid lines 230. The modified points 300 are thus arranged along the grid lines 230.

Since the distance between the peripheral region 120 and the center point (O) of the substrate 100 is no less than 10 mm, each of the modified points 300 is spaced apart from the center point (O) of the substrate 100 by a distance that is no less than 10 mm. Furthermore, two adjacent ones of the modified points 300 has a spacing D300. The spacing D300 is smaller than a minimum distance between the modified points 300 to the center point (O) of the substrate 100, i.e., mm. In some embodiments, the spacing D300 is not larger than 1 mm. In addition, two adjacent ones of the grid lines 230 has a spacing D230 that is smaller than the distance by which the peripheral region 120 is spaced apart from the center point (O) of the substrate 100. In some embodiments, the spacing D230 ranges from 20 μm to 10 mm.

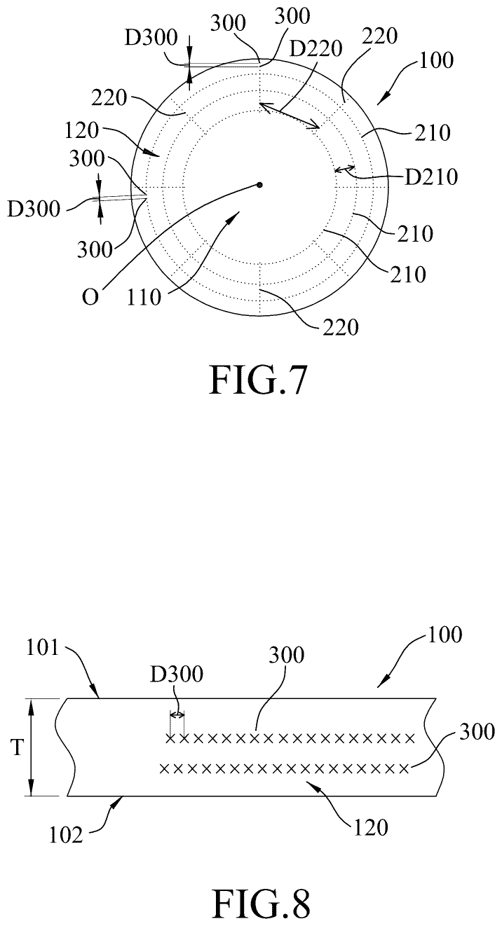

Referring to FIG. 7, a fourth example of the scan pattern includes a combination of the concentric circles 210 that are centered at the center point (O) of the substrate 100 and the radially-extending lines 220 that are directed to the center point (O) of the substrate 100. The modified points 300 are distributed along the concentric circles 210 and the grid lines 230 in the continuous or discontinuous manner in the interior of the substrate 100, and are formed by intermittently irradiating the peripheral region 120 with the laser beam along the concentric circles 210 and the grid lines 230. The modified points 300 are thereby formed in the peripheral region 120 along the concentric circles 210 that are centered at the center point (O) of the substrate 100 and the radially-extending lines 220 that are directed toward the center point (O) of the substrate 100.

Since the distance between the peripheral region 120 and the center point (O) of the substrate 100 is no less than 10 mm, the minimum radius for the concentric circles 210 is 10 mm. That is to say, each of the modified points 300 is spaced apart from the center point (O) of the substrate 100 by a distance that is no less than 10 mm. Furthermore, two adjacent ones of the modified points 300 has a spacing D300. The spacing D300 is smaller than a minimum distance of the modified points 300 to the center point (O) of the substrate 100, i.e., 10 mm. In some embodiments, the spacing D300 is not larger than 1 mm. In addition, two adjacent ones of the concentric circles 210 has a spacing D210 that is smaller than the distance by which the peripheral region 120 is spaced apart from the center point (O) of the substrate 100. In some embodiments, the spacing D210 ranges from 20 μm to 10 mm. Two adjacent ones of the radially-extending lines 220 has a spacing D220 that is smaller than the distance by which the peripheral region 120 is spaced apart from the center point (O) of the substrate 100. In some embodiments, the spacing D220 ranges from 20 μm to 10 mm.

In some embodiments, the substrate manufacturing method 10 for epitaxial growth further includes a step of polishing the first surface 101, which is performed before step S02. In certain embodiments, the step of polishing the first surface 101 is performed between step S01 and step S02.

Referring to FIG. 8, the modified points 300 are distributed in a discontinuous manner. The modified points 300 may be collectively formed into a shape of a circle, an ellipse or a polygon. The modified points 300 may be polycrystals (i.e., thermally modified structures), pores, vacancies, changes in atomic distances, changes in atomic ratios, spacings between atoms, dislocations, or combinations thereof. The shape or type of the modified points 300 may be determined by adjusting parameters of the laser beam such as wavelength, pulse duration, or pulse shape, etc. A range of the parameters of irradiation of the laser beam is listed in Table 1.

TABLE 1

| | | | | | | Size of | |
|---|---|---|---|---|---|---|---|
| | | | | | | laser | |
| | Pulse | | Wavelength | Power | Frequency | dots | Scan rate |
| | duration | | (nm) | (W) | (kHz) | (μm) | (mm/s) |
| Min | 1 | as | 200 | >0 | 1 | 0.1 | 10 |
| Max | 1 | ms | 5000 | 100 | 1000 | 1000 | 1000 |

After irradiation of the laser beam on the substrate 100 under the condition as listed in Table 1, the modified points 300 has a size ranging from 1 μm to 5 mm. The modified points 300 are formed in the peripheral region 120 of the substrate 100 at a depth ranging from 2% to 98% of the thickness (T) of the substrate 100 from the first surface 101. In some embodiments, the modified points 300 are formed at a depth ranging from 10% to 40% of the thickness (T) of the substrate 100 from the first surface 101. In other embodiments, the modified points 300 are formed at a depth ranging from 60% to 96% of the thickness (T) of the substrate 100 from the first surface 101. The modified points 300 may be distributed at the same depth, or may be independently distributed at different depths.

Referring to FIGS. 4 to 7, the modified points 300 in the peripheral region 120 of the substrate 100 are distributed in a continuous or discontinuous manner. Each of the modified points 300 has a distance to the center point (O) of the substrate 100 that is no less than 10 mm.

As described hereinbefore, the examples of the sapphire substrates fabricated in the prior art have surface profiles as shown in FIGS. 1A to 1C, which exhibits characteristics including distortion, bending, or warping due to uneven stress distribution that mainly occur at the peripheral region that is spaced apart from the center of the sapphire substrate by a distance no less than 10 mm, and the central region is almost flat. If the modified points 300 according to the disclosure are formed in the sapphire substrate shown in FIGS. 1A to 1C, whether in the form of polycrystals or pores, would cause a change in volume of the sapphire substrate and result in an increased stress therein, such that a localized portion of the sapphire substrate where the modified points 300 are formed would be subjected to a higher amount of stress. If the modified points 300 are uniformly formed in the interior of a central region and a peripheral region of a sapphire substrate as fabricated in the prior art, the stress generated across the sapphire substrate would be similar, resulting in the same extent of change in the curvature. Therefore, the resulting curvature across the sapphire substrate would still be non-uniform, and the sapphire substrate could not have the concentric circles-type profile shown in FIG. 1D. In the method according to this embodiment, only the interior of the sapphire substrate corresponding in position to the peripheral region, where distortion, bending, or warping most often occur due to uneven stress distribution, is formed with the modified points 300 by irradiation of the laser beam so as to release excessive stress in the peripheral region. Preferably, the peripheral region is spaced apart from the center of the sapphire substrate by a distance that is no less than 10 mm. Thus, the curvature and bending direction of the peripheral region tends to be consistent, and the surface profile of the sapphire substrate may exhibit concentric circles. If the sapphire substrate with such surface profile is selected for subsequent processing, the surface profile of the sapphire substrate will remain unchanged after subsequent processing, and curvature of the entire sapphire substrate will be more consistent.

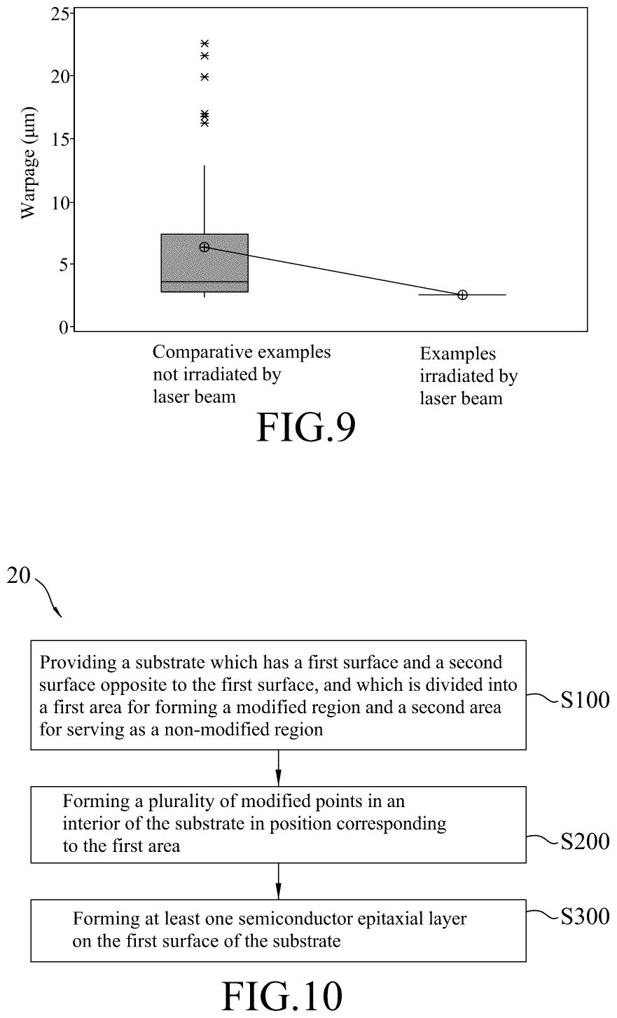

In order to verify a surface profile of the substrate 100 of the disclosure, warpage values of comparative examples (a conventional substrate not irradiated by the laser beam) and warpage values of examples (the substrate 100 irradiated by the laser beam) are shown in FIG. 9 using a box plot. The warpage is measured using a flatness-measuring instrument, such as GSS provided by Cheng Mei Instrument Technology. In addition, warpage values of the examples of the sapphire substrates as shown in FIGS. 1A to 1D are listed in Table 2 for use as reference data for evaluating the warpage values of the examples and the comparative examples shown in FIG. 9.

TABLE 2

| | Concentric | | | Concentric |
|---|---|---|---|---|
| Surface profile | circle-type | Saddle-type | Cylinder-type | ellipse-type |
| Warpage (μm) | 1~1.5 | >2.5 | <1 | 1.5~2.5 |

Referring back to FIG. 9, the warpage of the comparative examples has an average value of 3.18 μm and a standard deviation of 3.47 μm. Warpage of the examples of the disclosure (i.e., irradiated by the laser beam) has an average value of 1.01 μm and a standard deviation of 0.04 μm. According to Table 2, the average value of the warpage of the substrate 100 is within the range of the warpage of the concentric circles-type profile, i.e., ranging from 1 μm to 1.5 μm. Hence, the surface profile of the substrate 100 is classified as the concentric circles-type profile. Furthermore, the smaller standard deviation of warpage of the substrate 100 indicates improved uniformity of curvature distribution of the surface profile, which is beneficial for the consistency of the wavelength of light emitted from at least one semiconductor epitaxial layer disposed thereon.

### Embodiment 2

Referring to FIG. 10, a method 20 for manufacturing a semiconductor device includes steps S100, S200 and S300 in accordance with a second embodiment of the disclosure.

In step S100, a substrate (e.g., the substrate 100 obtained after step S02 of the method 10) is provided.

In step S200, the modified points 300 are formed through multi-photon absorption in the interior of the substrate 100 corresponding in position to the modified region by intermittently irradiating the peripheral region 120 (i.e., the first area) with a laser beam along the scan pattern arranged in the peripheral region 120.

In step S300, at least one semiconductor epitaxial layer is formed on the first surface of the substrate 100.

Details regarding the provision of the substrate (i.e., step S100) is similar to steps S01 and S02 as described above with reference to FIGS. 3A and 3B, and details regarding the formation of the modified points 300 (i.e., step S200) is similar to step S03 as described above with reference to FIGS. 4 to 8, and thus detailed description thereof is omitted herein.

The formation of the at least one semiconductor epitaxial layer includes disposing a first semiconductor layer 400 on the first surface 101 of the substrate 100, disposing a multi-quantum-well structure 500 on the first semiconductor layer 400 opposite to the substrate 100, and disposing a second semiconductor layer 600 on the multi-quantum-well structure 500 opposite to the first semiconductor layer 400. The second semiconductor layer 600 has a doping type that is opposite to the first semiconductor layer 400.

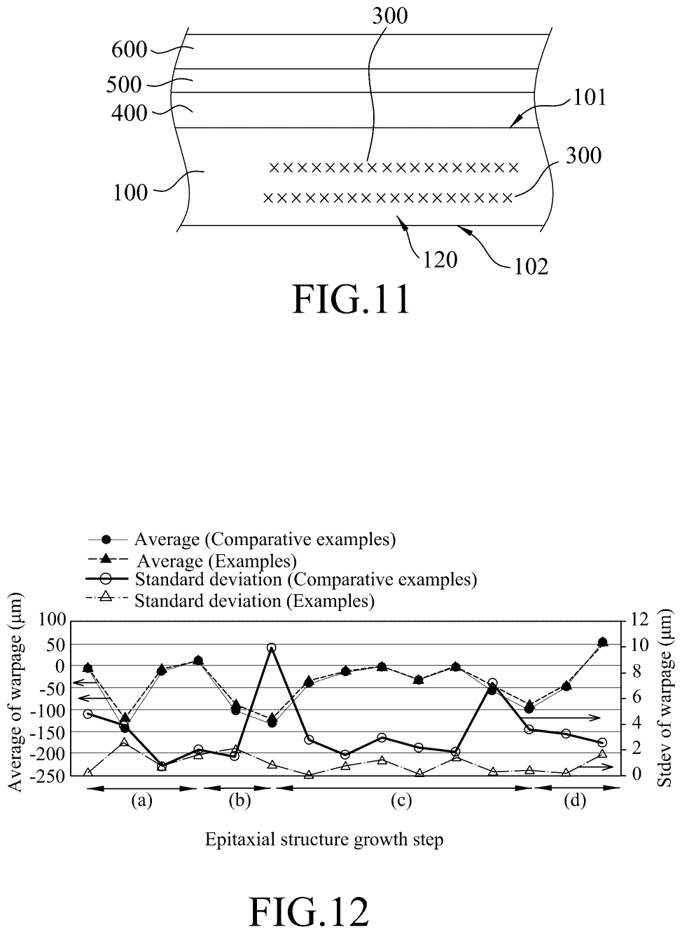

The semiconductor device obtained by the aforesaid method 20 includes the at least one semiconductor epitaxial layer formed on the abovementioned substrate 100. In some embodiments, the semiconductor device includes the abovementioned substrate 100, and the first semiconductor layer 400, the multi-quantum-well structure 500, and the second semiconductor layer 600 disposed on the first surface 101 of the substrate 100 in such order, as shown in FIG. 11.

FIG. 12 illustrates the variation of average and standard deviation of warpage during epitaxial growth of the comparative examples that are not irradiated by a laser beam and the examples that are irradiated by the laser beam. A process for manufacturing an epitaxial structure includes consecutive steps of epitaxial growth of a buffer layer (a), an n-type GaN-based layer (b), a multi-quantum-well structure (c), and a p-type layer (d) in such order. Test samples include the comparative examples of the conventional substrate and the examples of the substrate 100 that are made of sapphire. The test samples have a total sample size (N) of 1000. A sub-sample size (n1) of the comparative examples of the conventional substrate which are not irradiated by a laser beam is N/2, i.e., n1=500 and a sub-sample size (n2) of the examples of the substrate 100 which are irradiated by the laser beam is N/2, i.e., n2=500. Surface profile of the test samples includes four of the surface profiles shown in FIGS. 1A to 1D.

As shown in FIG. 12, the average of warpage of the examples of the substrate 100 is similar to that of the comparative examples of the conventional substrate at each consecutive step of the epitaxial growth of the epitaxial structure. However, the standard deviation of warpage of the examples of the substrate 100 is quite different from that of the comparative examples of the conventional substrate. To be specific, after epitaxial growth of the n-type GaN-based layer (b), standard deviation of warpage of the substrate 100 is about 0.6 μm and that of the conventional substrate is about 9.85 μm. During epitaxial growth of the multi-quantum-well structure (c), standard deviation of warpage of the substrate 100 is about 1.21 μm and that of the conventional substrate is about 2.54 μm. Evidently, from step (a) to step (d), the standard deviation of warpage of the examples of the substrate 100 is much lower than that of the conventional substrate. That is, surface profiles of the examples of the substrate 100 have relatively uniform curvature distribution.

In order to verify the improvement in uniformity of curvature distribution of the surface profiles of the substrate 100, standard deviation of light emission wavelength of a plurality of final products manufactured from the conventional substrate and the substrate 100 are investigated. A difference (Astdev) between standard deviation (Stdev₂) of light emission wavelength of the products manufactured from the substrate 100 and standard deviation (Stdev₁) of light emission wavelength of the products manufactured from the conventional substrate are listed in Table 3. The difference (Astdev) is obtained from an equation of Δstdev=((Stdev₂−Stdev₁)/Stdev₁)*100%.

TABLE 3

| | | | | Difference in |
|---|---|---|---|---|
| | Equipment | | | stdev. of light |
| | for epitaxial | Polishing | Light emission | emission |
| Final Products | growth | process | wavelength | wavelength |
| Display screen | Veeco RB | Single-sided | Green light | −17.6% |
| Micro LED | Veeco K465 | Single-sided | Green light | −21.5% |
| | | Single-sided | Blue light | −13.6% |
| | | Double-sided | Blue light | −24.8% |
| White light | Veeco K465 | Single-sided | Blue light | −11.1% |
| source | | | | |

The results in FIG. 12 and Table 3 show that an uniform stress distribution in the substrate 100 can be achieved when the modified points 300 are formed in the interior of the substrate 100 corresponding in position to the peripheral region 120, such that a surface profile of the substrate 100 is a concentric circles-type, thereby permitting a better light emission wavelength uniformity from an epitaxial structure disposed on the substrate 100. To be specific, the standard deviation of light emission wavelength is reduced by approximately 11% to 25%. Further, improvement of light emission wavelength uniformity of the epitaxial structure leads to an increase in the yield of resulting products manufactured from the epitaxial structure.

### Embodiment 3

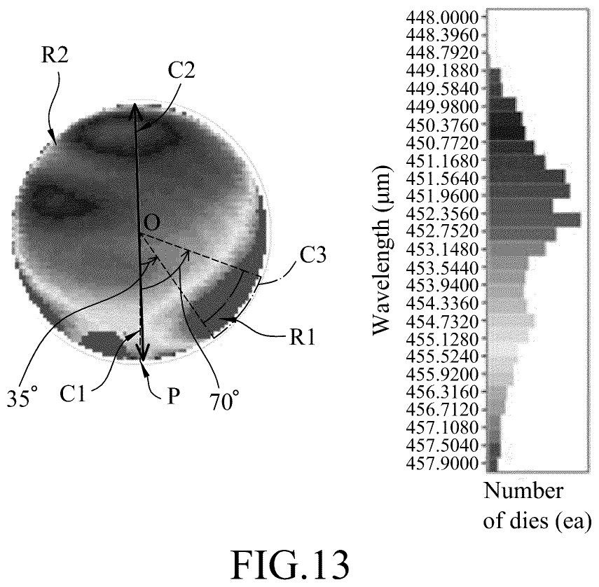

During an epitaxial growth, a high speed rotation is usually used to rotate a graphite disk (a carrier) supporting a substrate. Since the substrate is held in a groove of the graphite disk without moving relative to the disk, the substrate is exposed to unevenly-distributed warm zones and gas flow zones. As a result, emission wavelength at upwind and downwind slopes of the substrate after epitaxial growth are different. FIG. 13 is a diagram illustrating an emission wavelength distribution of a substrate (e.g., the substrate 100) after epitaxial growth. The substrate has a concentric circles-type profile and an even stress distribution therein. An emission wavelength from the substrate after epitaxial growth at a first region R1 shown in FIG. 13 is different from an emission wavelength from the substrate at a second region R2 shown in FIG. 13. Therefore, the uniformity of the wavelength emission from the substrate after epitaxial growth will be poor.

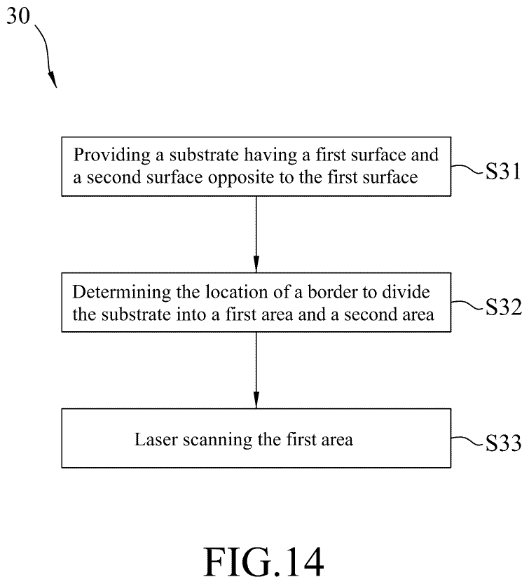

In FIG. 13, the first surface 101 of the substrate 100 faces upward (i.e., faces the viewer). An orientation marker (not shown) is located at a six o'clock position of the substrate (i.e., a lowest point (P) in FIG. 13). As shown in FIG. 13, an emission wavelength from the substrate 100 after epitaxial growth at a lower region C1 of the substrate 100 near the point (P) (closer to the upwind slope) is five nanometers greater than an emission wavelength at an upper region C2 (closer to the downwind slope) of the substrate 100 which is the furthest from the lower region C1. Especially, an emission wavelength at a lower right region C3 (closer to the upwind slope) of the substrate 100 is more than five nanometers greater than an emission wavelength at the upper region C1 (closer to the downwind slope) of the substrate 100. Therefore, in order to further improve uniformity of the wavelength of light emitted from the substrate after epitaxial growth, a substrate manufacturing method 30 is disclosed in accordance with a third embodiment. Referring to FIG. 14, the method 30 includes steps S31 to S33.

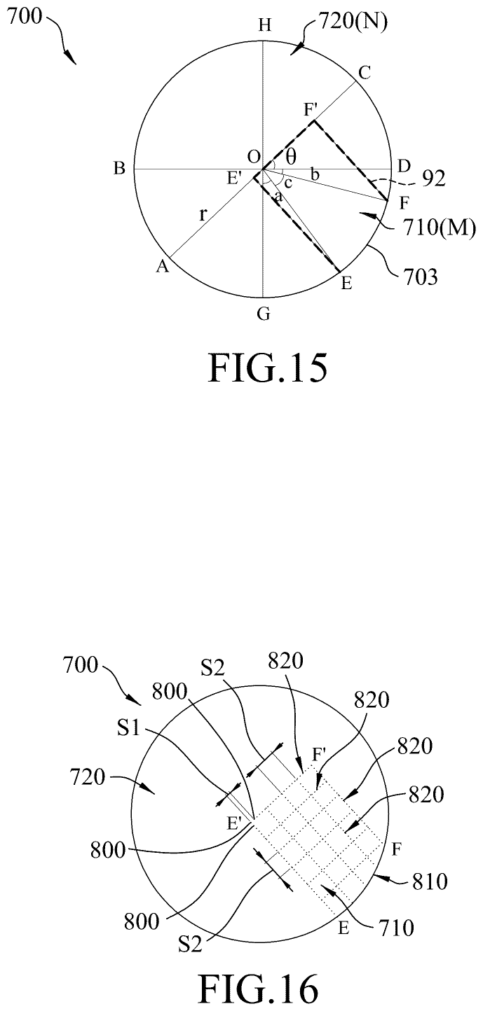

Referring to FIG. 15 in combination with FIG. 14, in step S31, a substrate 700 is provided. The substrate 700 has a structure similar to that of the substrate 100, and has a first surface to be processed and a second surface opposite to the first surface. The substrate 700 further includes an orientation marker (not shown) disposed at a point (G) on an edge 703 of the substrate 700.

In step S32, the location of a border 92 to divide the substrate 700 into a first area 710 and a second area 720 is determined. The first area 710 is for forming a modified region (M) of the substrate 700 and the second area 720 is for serving as a non-modified region (N) of the substrate 700. The border 92 is between the first and second areas 710, 720. When being viewed from above the first surface, the substrate 700 has a circular shape and the center point (O). The substrate 700 further includes: a point (E) which is located on the edge 703 of the substrate 700 and which is offset counterclockwise about the center point (O) from the point (G) by an angle that ranges from 30 degrees to 40 degrees; a point (F) which is located on the edge 703 of the substrate 700 and which is offset counterclockwise about the center point (O) from the point (G) by an angle that ranges from 65 degrees to 75 degrees; a straight line (BD) which extends through the center point (O), which is normal to a straight line (OG) connecting the center point (O) and the point (G) and which intersects the edge 703 of the substrate 700 at a point (B) and a point (D); a straight line (AC) which is obtained upon counterclockwise rotation of the straight line (BD) about the center point (O) by an angle that ranges from 30 degrees to 60 degrees, and which intersects the edge 703 of the substrate 700 at a point (A) and a point (C); a point (E′) which is obtained upon projection of the point (E) on the straight line (AC); and a point (F′) which is obtained upon projection of the point (F) on the straight line (AC). The first area 710 is a region defined by an arc section (EF) connecting the point (E) and the point (F), a straight line (FF′) connecting the point (F) and the point (F′), a straight line (F′E′) connecting the point (F′) and the point (E′), and a straight line (E′E) connecting the point (E′) and the point (E). The border 92 between the first and second areas 710, 720 is defined by the arc section (EF), and the straight lines (FF′, F′E′, E′E), and is determined by locating the points (E, F, F′, E′). The first area 710 is partitioned by the border 92 from the second area 720.

As shown in FIG. 15, the substrate 700 may have a circular shape or a circle-like shape. In some embodiments, the substrate 700 has a diameter of 4 inches and the orientation marker may be in a form of a flat edge (which may be also referred to as a wafer flat). In some other embodiments, the substrate 700 may have a diameter of 6 inches or 8 inches, and the orientation marker may be in a form of a wafer notch. In yet some other embodiments, the substrate 700 may include two of the orientation markers which may be in a form of two flat edges, in a form of two wafer notches, or in a form of one flat edge and one wafer notch. Other configurations of the orientation marker and other numbers of orientation markers are within the contemplated scope of the present disclosure.

In this embodiment, the substrate 700 shown in FIG. 15 is viewed from above the first surface, and the point (G) is located at a six o'clock position. When the substrate 700 includes a single orientation marker and the bottom edge 703 of the substrate 700 has a maximum radius (r) of the substrate 700, the substrate 700 is symmetric with respect to a diametrical straight line (HG) which extends through the center point (O) and which intersects the bottom edge 703 of the substrate 700 at the point (G) and a point (H). The orientation marker is located at the point (G). When the number of the orientation marker is two or more than two, one of the orientation markers is a main orientation marker and is located at the point (G). Then, the position of the point (E), the point (F), the straight line (BD), the straight line (AC), the point (E′), and the point (F′) can be determined in a manner similar to that as described above, and thus the first area 710 can be precisely defined.

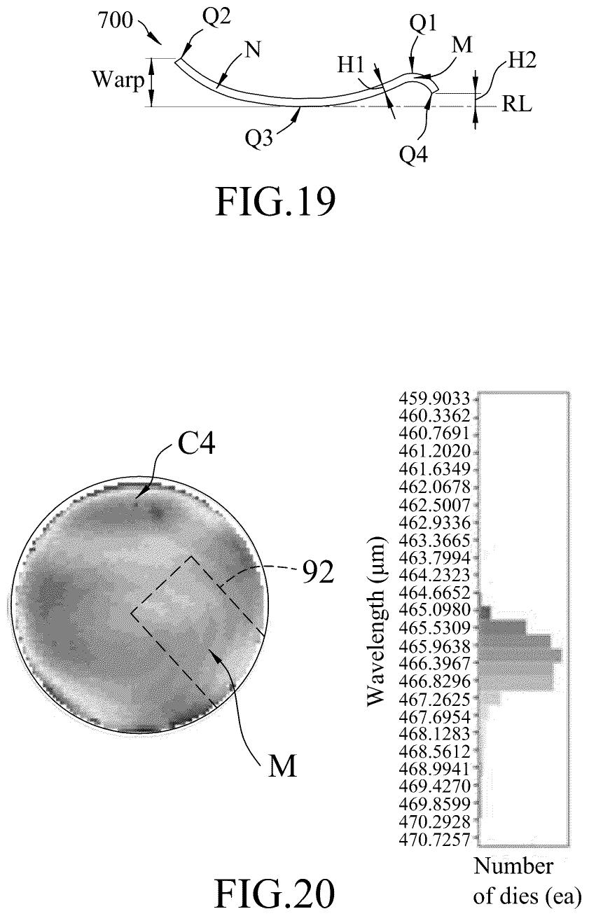

Referring again to FIG. 15, the point (E) is offset counterclockwise about the center point (O) from the point (G) by 35 degrees, and the point (F) is offset counterclockwise about the center point (O) from the point (G) by 70 degrees. The straight line (AC) is obtained upon counterclockwise rotation of the straight line (BD) about the center point (O) by 45 degrees. The substrate 700 can be selected from any type of substrate suitable for epitaxial growth. In some embodiments, the substrate 700 is made of sapphire, which is able to absorb multiple photons in an interior of the same, so as to form a plurality of modified points (e.g., the modified points 300 as described above with reference to FIG. 8) therein, thereby improving stress distribution in the substrate 700. The substrate 700 has a thickness (H, see FIG. 19) ranging from about 50 μm to about 10 mm, and a diameter ranging from about 4 inches to about 18 inches. The first surface of the substrate 700 is a surface for forming an epitaxial layer thereon. In some embodiments, the straight line (F′E′) has a length ranging from 20 mm to 150 mm.

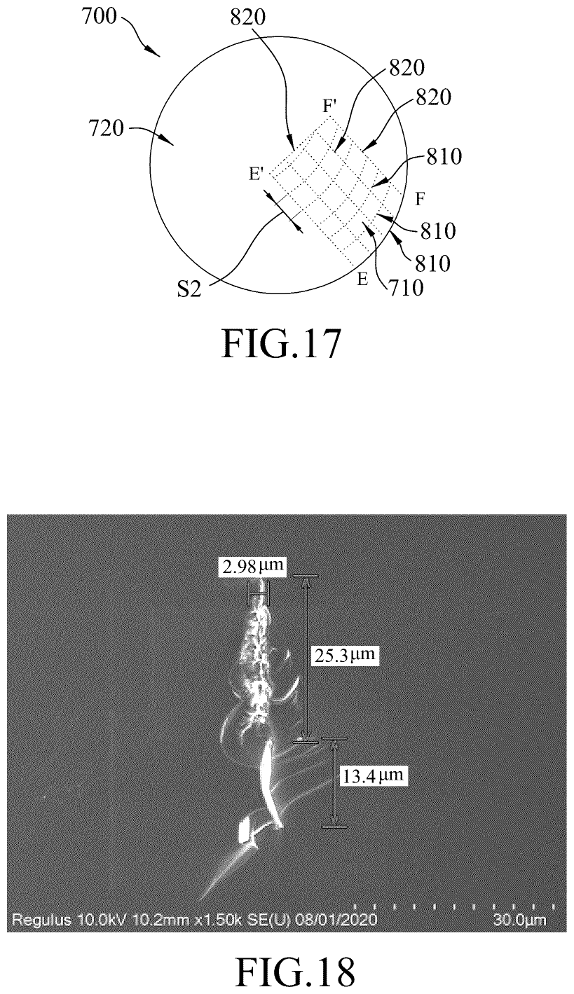

In step S33, the first area 710 is laser scanned with a laser beam to form a plurality of modified points 800 in the interior of the substrate 700, so that the first area 710 is converted in to the modified region (M) of the substrate 700. The laser beam scans the first area 710 of the substrate 700 from the first surface of the substrate 700. In some embodiments, a scan pattern used in laser scanning may include a combination of a single arcuate curve and multiple linear lines (see FIG. 16), and/or a combination of multiple arcuate curves and multiple linear lines (see FIG. 17). The single arcuate curve and multiple linear lines may form border lines connecting the points (E, F, F′, E′) for bordering the first area 710 (or the modified region). Multiple linear lines may intersect each other to form a grid. Alternatively, multiple linear lines may be parallel to each other or not parallel to each other.

In some embodiments, the laser beam is generated by a pulsed laser. During the laser scanning, the laser beam moves at a predetermined rate and direction and intermittently irradiates the first surface of the substrate 700. Discrete laser dots located at different positions form the scan pattern, and the modified points 800 are formed in the interior of the substrate 700 along the scan pattern in a continuous or discontinuous manner through multi-photon absorption.

In some embodiments, the substrate manufacturing method 30 further includes a step of polishing the first surface of the substrate 700, which is performed before step S33. The roughness of the first surface of the substrate 700 may be reduced after polishing the same, which is beneficial for focusing the laser beam and forming the modified points 800. Therefore, the warpage shape and/or the warpage degree (i.e., a difference between a maximum and a minimum stress in a substrate) of the substrate 700 can be precisely controlled.

Referring to FIG. 16, the scan pattern at the first area 710 is realized by a combination of the single arcuate curve 810 and multiple linear lines 820. The linear lines 820 may be parallel to the straight line (E′E) and the straight line (F′E′), or may not be parallel to the straight line (E′E) or the straight line (F′E′). In another example of this embodiment, as shown in FIG. 17, the scan pattern at the first area 710 is realized by a combination of multiple arcuate curves 810 and multiple linear lines 820. The arcuate curves 810 may be parallel to the arc section (EF) or not parallel to the arc section (EF), and the linear lines 820 may be parallel to the straight line (E′E) or not parallel to the straight line (E′E). The stress distribution may be effectively adjusted depending on layout of the scan pattern. The shape of the first area 710 and the layout of the scan pattern are not limited to those shown in FIGS. 16 and 17, and may have other configurations.

The modified points 800 are similar to the modified points 300 as described above in the first embodiment, but has the differences as described in the following. As shown in FIG. 16, two adjacent ones of the modified points 800 have a spacing 51 therebetween that ranges from 4 μm to 100 μm. As shown in FIGS. 16 and 17, two adjacent ones of scan paths (i.e., two adjacent ones of the arcuate curves 810 and/or two adjacent ones of the linear lines 820) have a spacing S2 therebetween ranging from 20 μm to 5 mm.

In this embodiment, the modified points 800 have a circular shape when being viewed from above the first surface. FIG. 18 illustrates a SEM image of the modified region of the substrate, wherein vacancies are formed in the substrate, and the molten substrate after solidification forms polycrystals around the vacancies, so that the modified region exhibits a phenomenon of whitening. In some other embodiments, with change of parameters of the laser beam, occurrence of lattice distortion, non-hexagonal lattice structures (i.e., changes in atomic distances), vacancies, changes in atomic ratios (i.e., atomic ratio is not two to three; as in sapphire (Al₂O₃), where the atomic ratio of aluminum to oxygen is two to three), dislocations, or combinations thereof may appear at the position of the modified points 800. In short, by varying stresses of the substrate 700 at the positions of the modified points 800, the height of the substrate 700 at the positions of the modified points 800 may be changed. Since thermal conduction between the substrate 700 and a carrier (not shown) is negatively correlated to the height (distance) of the substrate from the carrier, the substrate 700 may have a temperature distribution profile contrary to the surface profile of the substrate 700. That is, the temperature of the substrate 700 decreases at locations as the height of the substrate increases. Therefore, in this embodiment, the modified points 800 are formed in the interior of the substrate 700 at the first area 710 (i.e., the area (EFF′E′) through laser scanning, so that the substrate 700 is melted locally and then solidified, causing an increase in volume at the modified points 800 and an increased stress at the modified region. An uneven stress distribution in the interior of the substrate 700 causes the modified region to bend toward the second surface. That is, a distance between the modified region and the carrier changes. When the distance between the carrier and the substrate 700 at different positions complements or matches the distribution of wavelength shown in FIG. 13, the uniformity of temperature distribution of the substrate 700 may be improved accordingly, thereby optimizing a standard deviation of the wavelength of light emitted from the substrate 700 after epitaxial growth.

The shape or type of the modified points 800 may be controlled by adjusting parameters of the laser beam, such as wavelength, pulse duration, or pulse shape, etc. In this embodiment, the parameters for laser scanning the substrate 700 may be determined according to those listed in Table 1 of the first embodiment, and the details of the condition for laser scanning are omitted for the sake of brevity. After the substrate 700 is laser scanned, the modified points 800 are formed in the first defined area 710 of the substrate 700 at a depth ranging from 2% to 98% of the thickness (H, see FIG. 19) of the substrate 700 from the first surface. Each of the modified points 800, for example, the modified point shown in FIG. 18, may have a width ranging from 1 μm to 20 μm, a length ranging from 10 μm to 1 mm. The modified points 800 may be distributed at the same depth or at different depths in a substrate thickness direction. In some embodiments, the modified points 800 are formed at a depth ranging from 10% to 40% of the thickness (H1) of the substrate 700 from the first surface. In some other embodiments, the modified points 800 are formed at a depth ranging from 60% to 96% of the thickness (H1) of the substrate 700 from the first surface. It is noted that the position where the depth ranges from 10% to 40% of the thickness (H1) is closer to the first surface for epitaxial growth than the position where the depth ranges 60% to 96% of the thickness (H1).

In this embodiment, the substrate 700 for epitaxial growth which is obtained by the method 30 is also disclosed. After laser scanning the first area 710 (see FIG. 15), the substrate 700 becomes a modified substrate which has the modified region (M) and the non-modified region (N). The modified region (M) corresponds to the first area 710 after the first area 710 is modified by laser scanning. The non-modified region (N) corresponds to the second area 720 which remains un-modified. The modified region (M) is partitioned from the non-modified region (N) by the border 92 defined by the lines connecting the points (E, F, F′, E′) and has a plurality of the modified points 800 that are distributed in a pattern conforming to a scan pattern (such as the examples as described above with reference to FIGS. 16 and 17).

The modified region has an area ranging from 13.40% to 23.38% of an area of the first surface. The area of the first surface is calculated based on the maximum radius (r) of the substrate 700, and includes an area of the orientation marker which may be in a form of a flat edge, a wafer notch, or other suitable structures. Referring to Table 4 and FIG. 15, a ratio (R) of the area of the modified region (i.e., the area (EFF′E′) shown in FIG. 15) to the area of the first surface is calculated based on the parameters including an angle (O) formed between the straight line (AC) and the straight line (BD) being 30 degrees, 45 degrees, or 60 degrees, an angle (a) formed between the straight line (OG) and a straight line (OE) connecting the center point (O) and the point (E) being 30 degrees, 35 degrees, or degrees, and an angle (b) formed between a straight line (OF) connecting the center point (O) and the point (F) and a straight line (OD) connecting the center point (O) and the point (D) being 15 degrees, 20 degrees, or 25 degrees. An angle (c) can be obtained from an equation of c=90°−a−b. The area of the modified region (i.e., the area (EFF′E′) may be calculated from an area of a sector (S_{sector EOF}) defined by the point (E), the center point (O) and the point (F), an area of a first triangle (S_{ΔOFF′}) defined by the center point (O), the point (F) and the point (F′), and an area of a second triangle (S_{ΔOEE′}) defined by the center point (O), the point (E) and the point (E′). In Table 4, the areas (S_{sector EOF}, S_{ΔOFF′}, S_{ΔOEE′}) are calculated using π which is rounded to 3.14. It is noted that when an angle (EOE′) formed between the straight line (OE) and a straight line (OE′) connecting the center point (O) and the point (E′) is not greater than 90 degrees, the ratio (R) is obtained from an equation of R=(S_{sector EOF}+S_{ΔOFF′}+S_{ΔOEE′})/πr² and that when the angle (EOE′) is greater than 90 degrees, the ratio (R) is obtained from an equation of R=(S_{sector EOF}+S_{ΔOFF′}−S_{ΔOEE′})/πr². As the results listed in Table 4 show, the modified region has an area ranging from 13.40% to 23.38% of the area of the first surface.

TABLE 4

| Sample | θ | a | b | c | S_{sector EOF} | S_{ΔOFF′} | S_{ΔOEE′} | R |
|---|---|---|---|---|---|---|---|---|
| 1 | 30° | 30° | 15° | 45° | πr²*(45/360) | (rsin45°)*(rsin45°)/2 | 0 | 20.46% |
| 2 | 45° | 30° | 15° | 45° | πr²*(45/360) | (rsin30°)*(rsin60°)/2 | (rsin75°)*(rsin15°)/2 | 23.38% |
| 3 | 60° | 30° | 15° | 45° | πr²*(45/360) | (rsin15°)*(rsin75°)/2 | (rsin60°)*(rsin30°)/2 | 23.38% |
| 4 | 30° | 35° | 20° | 35° | πr²*(35/360) | (rsin40°)*(rsin50°)/2 | (rsin5°)*(rsin85°)/2 | 16.18% |
| 5 | 45° | 35° | 20° | 35° | πr²*(35/360) | (rsin25°)*(rsin65°)/2 | (rsin80°)*(rsin10°)/2 | 18.54% |
| 6 | 60° | 35° | 20° | 35° | πr²*(35/360) | (rsin10°)*(rsin80°)/2 | (rsin25°)*(rsin65°)/2 | 18.54% |
| 7 | 30° | 40° | 25° | 25° | πr²*(25/360) | (rsin40°)*(rsin50°)/2 | (rsin5°)*(rsin85°)/2 | 13.40% |
| 8 | 45° | 40° | 25° | 25° | πr²*(25/360) | (rsin20°)*(rsin70°)/2 | (rsin5°)*(rsin85°)/2 | 13.44% |
| 9 | 60° | 40° | 25° | 25° | πr²*(25/360) | (rsin5°)*(rsin85°)/2 | (rsin20°)*(rsin70°)/2 | 13.44% |

FIG. 19 is a side view of the substrate 700. The substrate 700 has an S-shaped profile when the substrate 700 is viewed in a direction perpendicular to the thickness direction of the substrate 700. Since the modified region (M) has a highest point (Q1) which is lower than a highest point (Q2) at the non-modified region (N), an amount of warpage (Warp) of the substrate 700 which is a distance between an uppermost point (Q2) and a bottommost point (Q3) of the substrate 700 is not changed after formation of the modified points 800.

In this embodiment, as shown in FIG. 19, the modified region (M) and the non-modified region (N) respectively have a point (Q4) and the point (Q2) located at the edge 703 (see FIG. 15) of the substrate 700. The lower point (Q4) has a height (H2) relative to a reference line (RL) less than that of the point (Q2) of the non-modified region (N) by 2 μm to 10 μm, thereby reducing the distance between the modified region (M) and the carrier (not shown). Accordingly, the temperature of the modified region (M) during an epitaxial growth process can be increased by 0.5 degree to 2 degrees. FIG. 20 is a diagram similar to FIG. 13, but illustrating a distribution of emission wavelength from the substrate 700 after epitaxial growth. It is worth noting that the difference between the longer light wavelength emitted at the modified region (M) and the shorter light wavelength emitted at an upper region C4 of the substrate 700 is reduced to be 0.5 nm or less than 0.5 nm, and that the standard deviation of light emission wavelength from the substrate 700 after epitaxial growth is reduced to range from 0.5 nm to 1 nm.

### Embodiment 4

In this embodiment, a method for manufacturing a semiconductor device includes the following steps, Firstly, the substrate 700 as shown in FIG. 15 is provided. The substrate 700 has the first surface and the second surface opposite to the first surface. The substrate 700 includes the orientation marker disposed at the point (G) on the edge 703 of the substrate 700. The substrate 700 is divided into the first area 710 and the second area 720. When being viewed from above the first surface, the substrate 700 has a circular shape and the center point (O). The substrate 700 further includes: the point (E) which is located on the edge 703 of the substrate 700 and which is offset counterclockwise about the center point (O) from the point (G) by an angle ranging from 30 degrees to 40 degrees; the point (F) which is located on the edge 703 of the substrate 700 and which is offset counterclockwise about the center point (O) from the point (G) by an angle ranging from 65 degrees to 75 degrees; the straight line (BD) which extends through the center point (O), which is normal to the straight line (OG) which intersects the edge 703 of the substrate 700 at the point (B) and the point (D); the straight line (AC) which is obtained upon counterclockwise rotation of the straight line (BD) about the center point (O) by an angle ranging from 30 degrees to 60 degrees; the point (E′) which is obtained upon projection of the point (E) on the straight line (AC); and the point (F′) which is obtained upon projection of the point (F) on the straight line (AC). The first defined area 710 is a region defined by the arc section (EF), the straight line (FF′), the straight line (F′E′), and the straight line (E′E).

Next, the laser beam scans the first area 710 of the substrate 700 from the first surface of the substrate 700 to form the modified points 800 in the interior of the substrate 700, thereby forming the modified region of the substrate 700.

Subsequently, at least one semiconductor epitaxial layer is formed on the first surface of the substrate 700.

Since the steps of providing the substrate 700 and scanning the laser beam as described above may be performed in a manner similar to that of the method 30 as described above in the third embodiment, the details thereof are omitted for the sake of brevity. The step of forming the at least one semiconductor epitaxial layer may be performed in a manner similar to that of step S300 of the method 20 as described above in the second embodiment, and includes: (i) forming the first semiconductor layer on the first surface; (ii) forming the at least one quantum well layer on the first semiconductor layer; and (iii) forming the second semiconductor layer on the at least one quantum well layer. The second semiconductor layer has a doping type opposite to that of the first semiconductor layer. The semiconductor device obtained by the aforesaid method 40 includes the at least one semiconductor epitaxial layer formed on the abovementioned substrate. In some embodiments, the semiconductor device includes the abovementioned substrate, and the first semiconductor layer, the at least one quantum well, and the second semiconductor layer disposed on the first surface of the substrate in such order.

In this embodiment, the substrate for epitaxial growth or the substrate of the semiconductor device is processed in a manner similar to that as described in the method 30, and thus the substrate after modification may have the same advantages as described in the third embodiment.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A substrate for epitaxial growth, comprising:
a first surface to be processed; and
a second surface opposite to said first surface,
wherein, when being viewed from above said first surface, said substrate is divided into a modified region and a non-modified region, said modified region being partitioned from said non-modified region by a border which is located at a predetermined position in said substrate, said modified region having a plurality of modified points.

2. The substrate as claimed in claim 1, wherein said substrate includes a central region which has a center point of said substrate and which serves as said non-modified region, and a peripheral region which surrounds said central region and which serves as said modified region, said border being located between said central and peripheral regions at a predetermined distance from said central point.

3. The substrate as claimed in claim 2, wherein said modified points are distributed in said modified region in a continuous or discontinuous manner.

4. The substrate as claimed in claim 2, wherein, when being viewed from above said first surface, said border is located at a distance no less than 10 mm from said center point of said substrate.

5. The substrate as claimed in claim 1, wherein
when being viewed from above said first surface, said substrate has a circular shape and a center point (O),
said substrate further includes
an orientation marker disposed at a point (G) on an edge of said substrate,
a point (E) which is located on said edge of said substrate and which is offset counterclockwise about said center point (O) from said point (G) by an angle ranging from 30 degrees to 40 degrees,
a point (F) which is located on said edge of said substrate and which is offset counterclockwise about said center point (O) from said point (G) by an angle ranging from 65 degrees to 75 degrees,
a straight line (BD) which extends through said center point (O), which is normal to a straight line (OG) connecting said center point (O) and said point (G) and which intersects said edge of said substrate at a point (B) and a point (D),
a straight line (AC) which is obtained upon counterclockwise rotation of said straight line (BD) about said center point (O) by an angle ranging from 30 degrees to 60 degrees,
a point (E′) which is obtained upon projection of said point (E) on said straight line (AC),
a point (F′) which is obtained upon projection of said point (F) on said straight line (AC), and
said border is located at an arc section (EF) connecting said point (E) and said point (F), a straight line (FF′) connecting said point (F) and said point (F′), a straight line (F′E′) connecting said point (F′) and said point (E′), and a straight line (E′E) connecting said point (E′) and said point (E).

6. The substrate as claimed in claim 5, wherein said modified region has an area ranging from 13.40% to 23.38% of an area of said first surface.

7. The substrate as claimed in claim 5, wherein said substrate has an S-shaped profile when said substrate is viewed in a direction perpendicular to a thickness direction of said substrate.

8. The substrate as claimed in claim 5, wherein said point (E) is offset counterclockwise about said center point (O) from said point (G) by 35 degrees, and said point (F) is offset counterclockwise about said center point (O) from said point (G) by 70 degrees.

9. The substrate as claimed in claim 5, wherein said straight line (F′E′) has a length ranging from 20 μm to 150 μm.

10. A substrate manufacturing method, comprising:
a) providing a substrate having a first surface for epitaxial growth and a second surface opposite to said first surface;
b) determining a location of a border to divide said substrate into a first area for forming a modified region and a second area for serving as a non-modified region; and
c) laser scanning said first area to form a plurality of modified points in said first area of said substrate through multi-photon absorption so that said first area is formed into said modified region.

11. The method as claimed in claim 10, wherein said modified points are formed in said first area of said substrate at a depth ranging from 10% to 96% of a thickness of said substrate from said first surface.

12. The method as claimed in claim 10, wherein step c) is carried out by intermittently laser scanning said first area such that said modified points are formed in a continuous or discontinuous manner through multi-photon absorption.

13. The method as claimed in claim 10, wherein said laser scanning is carried out along a scan pattern selected from a set of concentric circles that are centered at a center point (O) of said substrate, a set of linear lines, a single arcuate curve, a set of arcuate curves, or combinations thereof.

14. The method as claimed in claim 12, wherein said modified points formed in step c) are polycrystals, pores, vacancies, changes in atomic distances, changes in atomic ratios, spacings between atoms, dislocations, or combinations thereof.

15. The method as claimed in claim 10, wherein each of said modified points has a width ranging from 1 μm to 20 μm.

16. A method for manufacturing a semiconductor device, comprising:
providing a substrate for epitaxial growth, said substrate having a first surface and a second surface opposite to said first surface, said substrate including a modified region and a non-modified region partitioned from said modified region by a border which is located at a predetermined position in said substrate, said modified region having a plurality of modified points distributed in said modified region when being viewed from above said first surface; and
forming at least one semiconductor epitaxial layer on said first surface of said substrate.

17. The method as claimed in claim 16, wherein formation of said at least one semiconductor epitaxial layer includes
forming a first semiconductor layer on said first surface,
forming at least one quantum well layer on said first semiconductor layer, and
forming a second semiconductor layer on said at least one quantum well layer, said second semiconductor layer having a doping type opposite to that of said first semiconductor layer.

18. A semiconductor device, comprising:
said substrate for epitaxial growth as claimed in claim 1; and
at least one semiconductor epitaxial layer disposed on said substrate for epitaxial growth.
